(19) United States
(12) Patent Application Publication
(10) Pub. No.: US 2025/0179284 A1
(43) Pub. Date: Jun. 5, 2025

(54) FLEXIBLE ACRYLIC RESIN-MODIFIED POLYVINYLIDENE FLUORIDE FILM

(71) Applicant: Rohm and Haas Company, Collegeville, PA (US)

(72) Inventors: Hui Zhang, Shanghai (CN); Hailan Guo, Warrington, PA (US)

(21) Appl. No.: 18/993,098

(22) PCT Filed: Jul. 13, 2022
(86) PCT No.: PCT/CN2022/105415

§ 371 Date: Jan. 10, 2025

(51) Int. Cl. C08L 27/16; C08J 5/18

(52) U.S. Cl. CPC C08L 27/16; C08J 5/18; C08J 2327/16; C08J 2433/12; C08L 2207/53

(57) ABSTRACT

Provided are polymer compositions comprising a polyvinylidene fluoride resin and a multi-stage acrylic polymer. The multi-stage acrylic polymer comprises a cross-linked core, at least one intermediate layer, and a shell. Each of the cross-linked core and the shell comprise polymerized units derived from one or more alkyl(meth)acrylate monomers, and the one or more intermediate layers comprise polymerized units derived from one or more alkyl(meth)acrylate monomers, styrenic monomers, and combinations thereof. An article comprising the polymer composition and a photovoltaic module comprising a film comprising the polymer composition are also disclosed.

### FIELD OF THE INVENTION

This invention relates generally to flexible acrylic resin-modified polyvinylidene fluoride (PVDF) film.

### BACKGROUND

Polyvinylidene fluoride (PVDF) is an important member of fluoroplastic family. PVDF has excellent performance due to the chemical structure C—F bond resulting in excellent weatherability, chemical resistance and low moisture-vapor transmission rate. PVDF is often used as pipe material and as a lining material of storage tanks and reaction containers in chemical plants, interior and exterior plastics parts for architecture and automobiles, and also as surface protection films for metal plates or insulating materials for electric and electronic equipment.

In recent years, PVDF has been used as a weather resistant film in a back sheet of a photovoltaic solar panel module (for example, see Japanese Patent Application Publication No. JP2000294813A). Photovoltaic modules generally comprise at least one photovoltaic element encapsulated between a front layer and a back layer. The front layer is often glazed glass, providing weather resistance, anti-scratch and impact resistance, heat resistance, while still enabling maximum photoelectric conversion efficiency. The back layer is generally composed of polymer films and laminates to protect the photovoltaic cell and electric wiring from the environment. It may also be desirable for the back layer to reflect sunlight to further increase power generation efficiency of the photovoltaic module. An example of such a back sheet is disclosed in Japanese Published Patent Application No. JP2009071236A, which discloses a conventional photovoltaic module comprising a polyethylene terephthalate (PET) sheet laminated with a PVDF film containing white pigment. Titanium dioxide, TiO₂, is a preferred pigment for reflecting sunlight in photovoltaic modules.

A challenge associated with the use of PVDF results from PVDF's poor adhesion to other materials. In an attempt to overcome the poor adhesion, Japanese Patent No. JP H-05-50556 disclosed the introduction of polymethyl methacrylate (PMMA) into the PVDF to provide better adhesion with the PET sheet.

However, introducing PMMA into PVDF results in the reduction in the toughness of PVDF film. Generally, the PMMA-modified PVDF film becomes brittle and makes the film easily damaged during lamination.

One attempt to address the issues caused by modifying PVDF film with PMMA is disclosed in Chinese Registered Utility Model CN206553441U. In CN206663441U, a PMMA-modified PVDF film was further modified by adding a toughening agent to provide the desired toughness.

There are still issues of cracking in the protective PVDF films in photovoltaic modules. During installation and transport of photovoltaic modules, slight deformation of the module can occur. Deformation of the photovoltaic modules can also occur in use due to changes in temperature. This deformation can cause cracking of the PVDF films, which in turn can lead to moisture or oxygen entering the photovoltaic module. Moisture and oxygen can cause corrosion of the wiring, which can cause failure or decreased performance of the photovoltaic module.

Therefore, a need exists for PVDF films that can address the issues with existing solutions.

### SUMMARY OF THE INVENTION

One aspect of the invention provides a polymer composition comprising a polyvinylidene fluoride resin and a multi-stage polymer. The multi-stage acrylic polymer comprises a cross-linked core, at least one intermediate layer, and a shell. Each of the cross-linked core and the shell comprise polymerized units derived from one or more alkyl(meth)acrylate monomers, and the one or more intermediate layers comprise polymerized units derived from one or more alkyl(meth)acrylate monomers, styrenic monomers, and combinations thereof.

Another aspect of the present invention provides an article of manufacture comprising a polymer composition comprising a polyvinylidene fluoride resins and a multi-stage acrylic polymer. The multi-stage acrylic polymer comprises a cross-linked core, at least one intermediate layer, and a shell. Each of the cross-linked core and the shell comprise polymerized units derived from one or more alkyl(meth)acrylate monomers, and the one or more intermediate layers comprise polymerized units derived from one or more alkyl(meth)acrylate monomers, styrenic monomers, and combinations thereof.

Yet another aspect of the present invention relates to a photovoltaic module comprising a transparent front layer, a photovoltaic cell, and a back layer. The back layer comprises a film comprising a polymer composition comprising a polyvinylidene fluoride resin and a multi-stage acrylic resin. The multi-stage acrylic polymer comprises a cross-linked core, at least one intermediate layer, and a shell. Each of the cross-linked core and the shell comprise polymerized units derived from one or more alkyl(meth)acrylate monomers, and the one or more intermediate layers comprise polymerized units derived from one or more alkyl(meth)acrylate monomers, styrenic monomers, and combinations thereof.

### DETAILED DESCRIPTION

The inventors have now surprisingly found that polymer compositions comprising a polyvinylidene fluoride resin and a multi-stage acrylic polymer that has improved elongation and/or higher tear resistance. The multi-stage acrylic polymer comprises a cross-linked core, at least one intermediate layer, and a shell. Each of the cross-linked core and the shell comprise polymerized units derived from one or more alkyl(meth)acrylate monomers, and the one or more intermediate layers comprise polymerized units derived from one or more alkyl(meth)acrylate monomers, styrenic monomers, and combinations thereof.

As used herein, the term “polymer” refers to a polymeric compound prepared by polymerizing monomers, whether of the same or a different type. The generic term “polymer” includes the terms “homopolymer,” “copolymer,” “terpolymer,” and “resin.” As used herein, the term “polymerized units derived from” refers to polymer molecules that are synthesized according to polymerization techniques wherein a product polymer contains “polymerized units derived from” the constituent monomers which are the starting materials for the polymerization reactions. As used herein, the term “(meth)acrylate” refers to either acrylate or methacrylate or combinations thereof, and the term “(meth)acrylic” refers to either acrylic or methacrylic or combinations thereof.

As used herein, the term “phr” means per hundred parts resin or polymer solids. As used herein, the term “molecular weight” or “weight average molecular weight” or “M_{w}” refers to the weight average molecular weight of a polymer as measured by gel permeation chromatography (“GPC”), for acrylic polymers against polystyrene calibration standards following ASTM D5296-11 (2011), and using tetrahydrofuran (“THF”) as the mobile phase and diluent. As used herein, the term “particle size” means the weight average particle size of the emulsion (co)polymer particles as measured using a Brookhaven BI-90 Particle Sizer.

As used herein, the terms “glass transition temperature” or “T_{g}” refers to the temperature at or above which a glassy polymer will undergo segmental motion of the polymer chain. Glass transition temperatures of a copolymer can be estimated by the Fox equation (Bulletin of the American Physical Society, 1 (3) Page 123 (1956)) as follows:

$$1 / {T}_{g} = {w}_{1} / {T}_{g ( 1 )} + {w}_{2} / {T}_{g ( 2 )}$$

For a copolymer, w₁ and w₂ refer to the weight fraction of the two comonomers, and T_{g(1)} and T_{g(2)} refer to the glass transition temperatures of the two corresponding homopolymers made from the monomers. For polymers containing three or more monomers, additional terms are added (wₙ/T_{g(n)}). The glass transition temperatures of the homopolymers may be found, for example, in the “Polymer Handbook,” edited by J. Brandrup and E. H. Immergut, Interscience Publishers. The T_{g} of a polymer can also be measured by various techniques, including, for example, differential scanning calorimetry (“DSC”). As used herein, the phrase “calculated T_{g}” shall mean the glass transition temperature as calculated by the Fox equation.

The inventive polymer compositions preferably comprise the multi-stage acrylic polymer in an amount ranging from 5 to 40 weight %, based on the total weight of the multi-stage acrylic polymer and the polyvinylidene fluoride resin in the polymer composition. Preferably, the multi-stage acrylic polymer is present in an amount ranging from 10 to 35 weight %, and more preferably from 15 to 30 weight %, based on the total weight of the multi-stage acrylic polymer and the polyvinylidene fluoride resin the polymer composition.

The multi-stage acrylic polymer comprises cross-linked core, one or more intermediate layers, and a shell. Each of the cross-linked core and the shell comprise polymerized units derived from one or more alkyl(meth)acrylate monomers, and the one or more intermediate layers comprise polymerized units derived from one or more alkyl(meth)acrylate monomers, styrenic monomers, and combinations thereof. Preferably, the cross-linked core is present in the multi-stage polymer in an amount of from 25 to 45 weight %, preferably of from 30 to 40 weight %, and more preferably of from 32 to 38 weight %, based on the total weight of the multi-stage polymer. The one or more intermediate layers are present in the multi-stage polymer in an amount of from 30 to 70 weight, preferably from 40 to 65 weight %, more preferably from 45 to 60 weight %, based on the total weight of the multi-stage polymer. The shell is present in the multi-stage polymer in an amount of from 5 to 25 weight %, preferably of from 10 to 20 weight %, and more preferably of from 12 to 18 weight %, based on the total weight of the multi-stage polymer.

Preferably, the one or more intermediate layers comprise a first intermediate layer and a second intermediate layer. When a first intermediate layer and second intermediate layer are present, the first intermediate layer is present in the multi-stage polymer in an amount of from 25 to 45 weight %, preferably of from 30 to 40 weight %, and more preferably of from 32 to 38 weight %, based on the total weight of the multi-stage polymer. In certain embodiments, the second intermediate layer is present in the multi-stage polymer in an amount of from 5 to 25 weight %, preferably of from 10 to 20 weight %, and more preferably of from 12 to 18 weight %, based on the total weight of the multi-stage polymer.

The cross-linked core of the inventive multi-stage polymer comprises polymerized units derived from one or more alkyl(meth)acrylate monomers. The alkyl(meth)acrylate monomers comprise linear and branched alkyl(meth)acrylates wherein the alkyl group has from 1 to 12 carbon atoms. Suitable alkyl(meth)acrylate monomers include, for example, methyl methacrylate, ethyl acrylate, butyl acrylate, butyl methacrylate, ethyl hexyl acrylate, cyclopentyl acrylate, cyclohexyl acrylate, benzyl acrylate, benzyl methacrylate, and isooctylacrylate. Preferably, the alkyl(meth)acrylate monomers of the cross-linked core comprise butyl acrylate. The alkyl(meth)acrylate monomers may be present in the cross-linked core in an amount of from 95 to 99.9 weight %, preferably of from 97 to 99.5 weight %, and more preferably of from 98 to 99 weight %, based on the total weight of the cross-linked core.

The cross-linked core of the inventive multi-stage polymer may further comprise polymerized units derived from one or more cross-linking monomers, graft-linking monomers, and combinations thereof. Suitable cross-linking and graft-linking monomers include, for example, butanediol di(meth)acrylate, ethylene glycol di(meth)acrylate, divinyl benzene, diethylene glycol di(meth)acrylate, diallyl maleate, allyl acrylate, allyl methacrylate, diallyl phthalate, triallyl phthalate, and trimethylolpropane tri(meth)acrylate. The cross-linking monomers and graft-linking monomers of the cross-linked core may comprise 1,3-butandeiol diacrylate, 1,3-butanediol dimethacrylate, 1,4-butanediol diacrylate, 1,4-butanediol dimethacrylate, and allyl(meth)acrylate. The cross-linking monomers and graft-linking monomers may be present in the cross-linked core in an amount of from 0.1 to 5 weight %, preferably of from 0.5 to 3 weight %, and more preferably of from 1 to 2 weight %, based on the total weight of the cross-linked core.

The cross-linked core of the inventive multi-stage polymer preferably has a calculated T_{g} of −85° C. or more, −70° C. or more, or −60° C. or more. The cross-linked core of the inventive multi-stage polymer may have a calculated T_{g} of −10° C. or less, −30° C. or less, or −40° C. or less.

The one or more intermediate layers of the inventive multi-stage polymer comprises polymerized units derived from one or more alkyl(meth)acrylate monomers, styrenic monomers, and combinations thereof. The alkyl(meth)acrylate monomers comprise linear and branched alkyl(meth)acrylates wherein the alkyl group has from 1 to 12 carbon atoms. Suitable alkyl(meth)acrylate monomers include, for example, methyl methacrylate, ethyl acrylate, butyl acrylate, butyl methacrylate, ethyl hexyl acrylate, cyclopentyl acrylate, cyclohexyl acrylate, benzyl acrylate, benzyl methacrylate, and isooctylacrylate. Suitable styrenic monomers include, for example, styrene, alpha-methylstyrene, and vinyl toluene.

Preferably, the one or more intermediate layer comprise a first intermediate layer and a second intermediate layer. The first intermediate layer preferably comprises polymerized units derived from one or more alkyl(meth)acrylate monomers. Suitable alkyl(meth)acrylate monomers include, for example, methyl methacrylate, ethyl acrylate, butyl acrylate, butyl methacrylate, ethyl hexyl acrylate, cyclopentyl acrylate, cyclohexyl acrylate, benzyl acrylate, benzyl methacrylate, and isooctylacrylate. The alkyl(meth)acrylate monomers of the first intermediate layer preferably comprise butyl acrylate and methyl methacrylate. The alkyl(meth)acrylate monomers may be present in the first intermediate layers in an amount of from 95 to 100 weight %, preferably of from 97 to 99.9 weight %, and more preferably of from 99 to 99.9 weight %, based on the total weight of the one or more intermediate layers.

The first intermediate layer of the inventive multi-stage polymer may further comprise polymerized units derived from one or more cross-linking monomers, graft-linking monomers, and combinations thereof. Suitable cross-linking and graft-linking monomers include, for example, butanediol di(meth)acrylate, ethylene glycol di(meth)acrylate, divinyl benzene, diethylene glycol di(meth)acrylate, diallyl maleate, allyl methacrylate, allyl acrylate, diallyl phthalate, triallyl phthalate, and trimethylolpropane tri(meth)acrylate. The cross-linking monomers and graft-linking monomers of the first intermediate layer may comprise allyl methacrylate. The cross-linking monomers and graft-linking monomers may be present in the first intermediate layer in an amount of from 0 to 5 weight %, preferably of from 0.1 to 3 weight %, and more preferably of from 0.1 to 1 weight %, based on the total weight of the first intermediate layer.

The first intermediate layer may be composed of multiple sub-layers, each of which independently contains polymerized units derived from the monomer compositions described above for the entirety of the first intermediate layer. The first intermediate layer may contain, for example, comprise one, two, three, four, or five sub-layers. The first intermediate layer contains a compositional gradient between the sub-layers such that the T_{g} transitions from a minimum to a maximum over the width of the entire first intermediate layer. In certain embodiments, the calculated T_{g} transitions from a lower limit of −30° C., −25° C., −15° C., or 0° C., to an upper limit of 70° C., 55° C., 35° C., or 15° C. While not wishing to be bound by theory, it is believed that the compositional gradient is achieved by the proper selection of and manner and timing of addition of monomers during the emulsion polymerization process used to prepare the first intermediate layer. A multi-stage polymerization process may be used during which monomers are added in stages, rather than all at once, to the emulsion polymerization reactor (or reactor vessel), permitting an interpenetration of one layer into adjacent layers resulting in a T_{g} gradient over the first intermediate layer.

The second intermediate layer of the inventive multi-stage polymer may comprise one or more of alkyl(meth)acrylate monomers, styrenic monomers, and combinations thereof. The alkyl(meth)acrylate monomers comprise linear and branched alkyl(meth)acrylates wherein the alkyl group has from 1 to 12 carbon atoms. Suitable alkyl(meth)acrylate monomers include, for example, methyl methacrylate, ethyl acrylate, butyl acrylate, butyl methacrylate, ethyl hexyl acrylate, cyclopentyl acrylate, cyclohexyl acrylate, benzyl acrylate, benzyl methacrylate, and isooctylacrylate. Suitable styrenic monomers include, for example, styrene, alpha-methylstyrene, and vinyl toluene. The alkyl(meth)acrylate monomers of the second intermediate layer preferably comprises butyl acrylate and methyl methacrylate. The alkyl(meth)acrylate monomers may be present in the second intermediate layer in an amount of from 98 to 100 weight %, preferably of from 98.5 to 99.5 weight %, and more preferably of from 98.7 to 99.3 weight %, based on the total weight of the second intermediate layer.

The second intermediate of the inventive multi-stage polymer may further comprise polymerized units derived from one or more chain transfer agents. Suitable chain transfer agents include, for example, 1-dodecanethiol, t-dodecanethiol, thioethanol, hexanethiol, mercaptopropionic acid, methyl-3-mercaptopropionate, and butyl-3-mercaptopropionate. The chain transfer agents of the second intermediate layer preferably comprise 1-dodecanethiol. The chain transfer agents may be present in the second intermediate layer in an amount of from 0 to 2 weight %, preferably of from 0.5 to 1.5 weight %, and more preferably of from 0.7 to 1.3 weight %, based on the total weight of the second intermediate layer.

The second intermediate layer of the inventive multi-stage polymer may have a calculated T_{g} of 40° C. or more, 45° C. or more, or 65° C. or more. The second intermediate layer of the inventive multi-stage polymer may have a calculated T_{g} of 110° C. or less, 95° C. or less, or 80° C. or less.

The shell of the inventive multi-stage polymer comprises one or more of alkyl(meth)acrylate monomers, styrenic monomers, and combinations thereof. The alkyl(meth)acrylate monomers comprise linear and branched alkyl(meth)acrylates wherein the alkyl group has from 1 to 12 carbon atoms. Suitable alkyl(meth)acrylate monomers include, for example, methyl methacrylate, ethyl acrylate, butyl acrylate, butyl methacrylate, ethyl hexyl acrylate, cyclopentyl acrylate, cyclohexyl acrylate, benzyl acrylate, benzyl methacrylate, and isooctylacrylate. Suitable styrenic monomers include, for example, styrene, alpha-methylstyrene, and vinyl toluene. The alkyl(meth)acrylate monomers of the shell preferably comprise butyl acrylate and methyl methacrylate. The alkyl(meth)acrylate monomers may be present in the shell in an amount of from 84 to 98 weight %, preferably of from 85 to 94 weight %, and more preferably of from 86 to 93 weight %, based on the total weight of the shell.

The shell of the inventive multi-stage polymers may further comprise one or more monomers selected from the group consisting of acid functionalized monomers, hydroxyl-functionalized monomers, and combinations thereof. Suitable examples of functionalized monomers include, for example, acid functionalized monomers and hydroxyl-functionalized monomers. Suitable examples of acid functionalized monomers include, for example, acrylic monomers having one or more carboxyl group, e.g., (meth)acrylic acid, itaconic acid, and phthalic acid. Preferably, the one or more acid functionalized monomers comprise acrylic acid. Suitable examples of hydroxyl-functionalized monomers include, for example, one or more hydroxy-substituted C₁-C₈alkyl (meth)acrylates. Preferably, one or more hydroxyl-functionalized monomers comprise hydroxyethyl methacrylate. The one or more monomers selected from the group consisting of acid functionalized monomers, hydroxyl-functionalized monomers, and combinations thereof may be present in the shell in an amount of from 2 to 16 weight %, preferably of from 3 to 14 weight %, and more preferably of from 5 to 12 weight %, based on the total weight of the shell.

The shell of the inventive multi-stage polymers may further comprise polymerized units derived from one or more chain transfer agents. Suitable chain transfer agents include, for example, 1-dodecanethiol, t-dodecanethiol, thioethanol, hexanethiol, mercaptopropionic acid, methyl-3-mercaptopropionate, butyl-3-mercaptopropionate. Preferably, the chain transfer agents of the shell comprise 1-dodecanethiol. The chain transfer agents may be present in the shell in an amount of from 0 to 2 weight %, preferably of from 0.5 to 1.5 weight %, and more preferably of from 0.7 to 1.3 weight %, based on the total weight of the shell.

The shell of the inventive multi-stage polymer may have a calculated T_{g} in the range of 40° C. or more, 50° C. or more, or 65° C. or more. The shell of the inventive multi-stage polymer may have a calculated T_{g} of 100° C. or less, 90° C. or less, or 80° C. or less.

The shell of the inventive multi-stage polymer may have a weight average molecular weight (M_{w}) in the range of from 20,000 to 100,000 g/mol, 30,000 to 60,000 g/mol, 40,000 to 60,000 g/mol, or 40,000 to 50,000 g/mol.

The inventive multi-stage polymers may have a particle size in the range of from 30 to 250 nm, preferably of from 50 to 200 nm, more preferably of from 60 to 175 nm, and even more preferably of from 90 to 150 nm, as measured by a Brookhaven BI-90 Particle Sizer.

Suitable polymerization techniques for preparing the polymers contained in the inventive polymer compositions include, for example, emulsion polymerization and solution polymerization, preferably emulsion polymerization, as disclosed in U.S. Pat. No. 6,710,161. Aqueous emulsion polymerization processes typically are conducted in an aqueous reaction mixture, which contains at least one monomer and various synthesis adjuvants, such as the free radical sources, buffers, and reductants in an aqueous reaction medium. A chain transfer agent may be used to limit molecular weight. The aqueous reaction medium is the continuous fluid phase of the aqueous reaction mixture and contains more than 50 weight % water and optionally one or more water miscible solvents, based on the weight of the aqueous reaction medium. Suitable water miscible solvents include, for example, methanol, ethanol, propanol, acetone, ethylene glycol ethyl ethers, propylene glycol propyl ethers, and diacetone alcohol. The aqueous reaction medium may contain more than 90 weight % water, preferably more than 95 weight % water, and more preferably more than 98 weight % water, based on the weight of the aqueous reaction medium.

The inventive polymer compositions may also contain other optional ingredients that include, for example, plasticizers, antioxidants, UV absorbers and light stabilizers, dyes, pigments, flame retardant agents, and other additives to prevent, reduce, or mask discoloration or deterioration caused by heating, aging, or exposure to light or weathering. The amount of optional ingredients effective for achieving the desired property provided by such ingredients can be readily determined by one skilled in the art.

The polymer compositions of the present invention have end use applications including, for example, as sheets and films for use in photovoltaic modules. The inventive multi-stage polymer compositions can be processed into a film and/or sheet by way of extrusion blowing, extrusion casting, calendaring, hot pressing or injection molding. Sheets and films made from the inventive polymer composition may have any appropriate thickness. In one embodiment, the sheets or films have a thickness of from 20 to 500 microns.

According to an aspect of the present invention, a photovoltaic module comprises a transparent front layer, a photovoltaic cell, and a back layer comprising a film comprising a polymer composition comprising a polyvinylidene fluoride resin and a multi-stage acrylic polymer. Preferably, the polymer composition further comprises a reflective pigment, such as, for example, titanium dioxide (TiO₂).

Some embodiments of the invention will now be described in detail in the following Examples.

### EXAMPLES

### Example 1

### Preparation of Exemplary Polymer Composition

The PVDF compounds were produced through a co-rotating twin screw extruder around 230° C. melt temperature, then the films were produced by a laboratory hot-pressor at 220° C., the film thickness was targeted as 200 microns. The inventive polymer composition comprised a multi-stage acrylic polymer (VERSALOID™ 21308-XP from The Dow Chemical Company) and a polyvinylidene fluoride resin (DongYue DS206), where the multi-stage acrylic polymer was present in an amount of 29.5 phr relative to the weight of the polyvinylidene fluoride resin. In a comparative example, 29.5 phr of a toughened polymethyl methacrylate polymer (Evonik 8N PMMA blend with a PARALOID™ EXL-2315 impact modifier from The Dow Chemical Company) was substituted for the multi-stage acrylic polymer. The inventive example and the comparative example contained identical pigment, processing aids, and anti-oxidants. As shown below in Table 1, the inventive example exhibited superior tensile elongation and tear strength compared to the comparative example. To simulate aging, films were exposed to a temperature of 121° C. at 100% relative humidity at 2 atm pressure for 96 hours.

TABLE 1

| | Comparative | Inventive |
|---|---|---|
| | Example | Example |
| MFI (g/10 min), 230° C./5 kg, | 9.9 | 9.7 |
| 4 min soaking | | |
| Tensile Elongation (%) | 5.15 | 9.28 |
| Tensile Elongation, Aged (%) | 3.67 | 6.70 |
| Tear Strength (cN) | 655.6 | 725.6 |
| Tear Strength, Aged (cN) | 333.5 | 471.3 |

What is claimed is:

1. A polymer composition comprising:
a polyvinylidene fluoride resin; and
a multi-stage acrylic polymer, wherein the multi-stage acrylic polymer comprises a cross-linked core, one or more intermediate layers, and a shell, wherein each of the cross-linked core and the shell comprise polymerized units derived from one or more alkyl(meth)acrylate monomers and the one or more intermediate layers comprise polymerized units derived from one or more alkyl(meth)acrylate monomers, styrenic monomers, and combinations thereof.

2. The polymer composition of claim 1, wherein the multi-stage acrylic polymer comprises:
(a) 25 to 45 weight % of the cross-linked core, based on the total weight of the multi-stage polymer, comprising polymerized units derived from (i) 95 to 99.9 weight % of one or more alkyl(meth)acrylate monomers, and (ii) 0.1 to 5 weight % of one or more cross-linking monomers, graft-linking monomers, and combinations thereof, based on the total weight of the cross-linked core;
(b) 30 to 70 weight % of the one or more intermediate layers, based on the total weight of the multi-stage polymer, comprising polymerized units derived from (i) 95 to 100 weight % of one or more alkyl(meth)acrylate monomers, and (ii) 0 to 5 weight % of cross-linking monomers, graft-linking monomers, and combinations thereof, based on the total weight of the one or more intermediate layers;
(c) 5 to 25 weight % of the shell, based on the total weight of the multi-stage polymer, comprising polymerized units derived from (i) 84 to 98 weight % of one or more alkyl(meth)acrylate monomers, styrenic monomers, and combinations thereof, (ii) 2 to 16 weight % of one or more monomers selected from the group consisting of acid functionalized monomers, hydroxyl-functionalized monomers, and combinations thereof, and (iii) 0 to 2 weight % of one or more chain transfer agents, based on the total weight of the shell.

3. The composition of claim 1, wherein the one or more alkyl(meth)acrylate monomers of the cross-linked core, the one or more intermediate layers, and shell are selected from the group consisting of methyl methacrylate, ethyl acrylate, butyl acrylate, butyl methacrylate, ethyl hexyl acrylate, cyclopentyl acrylate, cyclohexyl acrylate, benzyl acrylate, benzyl methacrylate, isooctylacrylate, and combinations thereof.

4. The composition of claim 3, wherein the one or more alkyl(meth)acrylate monomers of the cross-linked core, the one or more intermediate layers, and shell are selected from the group consisting of butyl acrylate, methyl methacrylate, and combinations thereof.

5. The composition of claim 2, wherein the one or more monomers selected from the group consisting of acid functionalized monomers, hydroxyl-functionalized monomers, and combinations thereof comprises one or more of acrylic acid and hydroxyl ethyl methacrylate.

6. The composition of claim 2, wherein the one or more cross-linking monomers, graft-linking monomers, and combinations thereof of the cross-linked core and one or more intermediate layer are selected from the group consisting of 1,3-butanediol diacrylate, 1,3-butanediol dimethacrylate, 1,4-butanediol diacrylate, 1,4-butanediol dimethacrylate, allyl methacrylate, and combinations thereof.

7. The composition of claim 1, wherein the one or more intermediate layers comprises a first intermediate layer and a second intermediate layer, wherein the first intermediate layer comprises polymerized units derived from (i) 95 to 100 weight % of one or more alkyl(meth)acrylate monomers, and (ii) 0 to 5 weight % of cross-linking monomers, graft-linking monomers, and combinations thereof, based on the total weight of the first intermediate layer, and the second intermediate layer comprises polymerized units derived from (i) 98 to 100 weight % of one or more alkyl(meth)acrylate monomers, styrenic monomers, and combinations thereof, and (ii) 0 to 2 weight % of one or more chain transfer agents, based on the total weight of the second intermediate layer.

8. The composition of claim 1, wherein the multi-stage acrylic polymer is present in an amount ranging from 5 weight % to 40 weight %, based on the total weight of the polyvinylidene fluoride resin and the multi-stage acrylic polymer.

9. The composition of claim 1, further comprising at least one reflective pigment.

10. An article of manufacture comprising the polymer composition of claim 1, wherein the article of manufacture is selected from the group consisting of a film and a sheet.

11. A photovoltaic module comprising:
a transparent front layer;
a photovoltaic cell; and
a back layer comprising a film comprising the polymer composition of claim 1.
